(19) United States
(12) Patent Application Publication
(10) Pub. No.: US 2025/0118574 A1
(43) Pub. Date: Apr. 10, 2025

(54) METHOD OF MANUFACTURING SEMICONDUCTOR PACKAGES

(71) Applicant: Samsung Electronics Co., Ltd., Suwon-si (KR)

(72) Inventors: Jeonggi Jin, Suwon-si (KR); Jinwoo Park, Suwon-si (KR); Byoungwook Jang, Suwon-si (KR); Byungmin Yu, Suwon-si (KR); Moogun Lee, Suwon-si (KR)

(21) Appl. No.: 18/826,678

(22) Filed: Sep. 6, 2024

(30) Foreign Application Priority Data
Oct. 5, 2023 (KR) 10-2023-0132191
Jan. 25, 2024 (KR) 10-2024-0011497

(51) Int. Cl. H01L 21/56; H01L 21/48; H01L 21/683; H01L 21/78; H01L 23/00

(52) U.S. Cl. CPC H01L 21/561; H01L 21/4853; H01L 21/6836; H01L 21/78; H01L 24/97; H01L 2224/95001

(57) ABSTRACT

A method of manufacturing a semiconductor package includes providing a fan-out wafer on a support member, where the fan-out wafer includes a plurality of package regions and a plurality of dummy regions along an edge of the fan-out wafer, and where the plurality of package regions are divided by a cutting region, attaching the fan-out wafer to an adhesive member that is on a ring frame, forming a sealing member along the edge of the fan-out wafer and on the adhesive member to at least partially surround a plurality of dummy packages on the plurality of dummy regions, and cutting the fan-out wafer along the cutting region to separate the plurality of package regions.

### CROSS-REFERENCE TO RELATED APPLICATIONS

This application claims priority under 35 U.S.C. § 119 to Korean Patent Application Nos. 10-2023-0132191, filed on Oct. 5, 2023 and 10-2024-0011497, filed on Jan. 25, 2024 in the Korean Intellectual Property Office (KIPO), the contents of which are herein incorporated by reference in their entirety.

### TECHNICAL FIELD

Example embodiments relate to a method of manufacturing a semiconductor package. More particularly, example embodiments relate to a method of manufacturing a fan-out wafer level package.

### BACKGROUND

When a fan-out wafer is adhered to an adhesive member and is carried using a ring frame to which the adhesive member is adhered, interfacial delamination may occur between the fan-out wafer and the adhesive member due to deterioration of the adhesion strength of the adhesive member that connects the fan-out wafer and the ring frame and warpage of the fan-out wafer, thereby increasing errors in subsequent processes. A region where such interfacial delamination occurs may continue to expand as the subsequent process progresses, making it difficult for subsequent processing apparatuses to recognize a thickness of the fan-out wafer, and process errors in subsequent processes become worse. Further, in a sawing process, semiconductor chips in an edge region may be separated, thereby damaging a blade. Therefore, there is a need to prevent the interfacial delamination of the adhesive member and the fan-out wafer.

### SUMMARY

Example embodiments provide a method of manufacturing a semiconductor package preventing interfacial delamination.

According to example embodiments, a method of manufacturing a semiconductor package includes providing a fan-out wafer on a support member, where the fan-out wafer includes a plurality of package regions and a plurality of dummy regions along an edge of the fan-out wafer, and where the plurality of package regions are divided by a cutting region, attaching the fan-out wafer to an adhesive member that is on a ring frame, forming a sealing member along the edge of the fan-out wafer and on the adhesive member to at least partially surround a plurality of dummy packages on the plurality of dummy regions, and cutting the fan-out wafer along the cutting region to separate the plurality of package regions.

According to example embodiments, a method of manufacturing a semiconductor package includes: providing a fan-out wafer on a support member, where the fan-out wafer includes a plurality of dummy regions along an edge of the fan-out wafer, a plurality of package regions includes a plurality of semiconductor chips, and a cutting region that divides the plurality of dummy regions and the plurality of package regions, attaching the fan-out wafer to an adhesive member that is on a ring frame, forming a sealing member on the adhesive member along the edge of the fan-out wafer to at least partially surround a plurality of dummy packages of the fan-out wafer on the plurality of dummy regions, and attaching the adhesive member to the fan-out wafer by irradiating the sealing member with light to cure the sealing member.

According to example embodiments, a method of manufacturing a semiconductor includes: providing a fan-out wafer on a support member, where the fan-out wafer includes a first surface and a second surface that are opposite to each other and a circumferential surface extending in a first direction that is perpendicular to the first surface, where the fan-out wafer includes a plurality of package regions that are on a central portion of the fan-out wafer and divided by a cutting region, and where the fan-out wafer includes a plurality of dummy regions along the circumferential surface of the fan-out wafer, attaching the fan-out wafer to an adhesive member that is on a ring frame, forming a sealing member along the circumferential surface of the fan-out wafer and on the adhesive member to surround at least portions of the fan-out wafer on the plurality of dummy regions, where the sealing member connects the circumferential surface of the fan-out wafer and a surface of the adhesive member, attaching the adhesive member to the fan-out wafer by irradiating the sealing member with light to cure the sealing member, and cutting the fan-out wafer along the cutting regions to separate a plurality of packages on the plurality of package regions, where the fan-out wafer, the adhesive member, and the sealing member are attached to each other while cutting the fan-out wafer.

According to example embodiments, in a method of manufacturing a semiconductor package, a fan-out wafer may be provided. The fan-out wafer may be attached on an adhesive member that is attached on a ring frame. A sealing member may be formed on the adhesive member along a circumference of the fan-out wafer to cover a plurality of dummy packages of the fan-out wafer. The fan-out wafer may be cut along the cutting region to individualize a plurality of packages on the plurality of package regions.

Forming the sealing member may include connecting a circumferential surface of the fan-out wafer and one surface of the adhesive member through the sealing member. Also, cutting the fan-out wafer may include keeping the plurality of dummy packages on the plurality of dummy regions attached to the sealing member.

Accordingly, the method of manufacturing a semiconductor package may prevent or inhibit the fan-out wafer and the adhesive member from separating from each other. Thus, an interfacial delamination phenomenon may be prevented from increasing errors of one or more subsequent processes. Furthermore, in the sawing process, the semiconductor chips may be prevented from being separated, and damage to a blade can thereby be inhibited or prevented.

### BRIEF DESCRIPTION OF THE DRAWINGS

FIG. 1 is a plan view illustrating a fan-out wafer in accordance with example embodiments.

FIG. 2 is a cross-sectional view taken along the line A-A′ in FIG. 1.

FIG. 3 is an enlarged cross-sectional view illustrating portion ‘M1’ in FIG. 2.

FIGS. 4 and 5 are cross-sectional views illustrating processes of attaching a ring frame on the fan-out wafer of FIG. 1 by using an adhesive member.

FIG. 6 is a cross-sectional view illustrating process of irradiating a laser on the fan-out wafer of FIG. 1

FIG. 7 is an enlarged view illustrating portion ‘M2’ in FIG. 6.

FIGS. 8 and 9 are views illustrating processes of separating the fan-out wafer of FIG. 1 from a support member.

FIG. 10 is a cross-sectional view illustrating a sealing member being formed.

FIG. 11 is a cross-sectional view illustrating light being irradiated on the sealing member of FIG. 10.

FIG. 12 is a plan view illustrating the sealing member of FIG. 11.

FIG. 13 is an enlarged view illustrating portion ‘M3’ in FIG. 11.

FIGS. 14 and 15 are views illustrating a metal layer being removed from the fan-out wafer of FIG. 1.

FIGS. 16 and 17 are views illustrating a plurality of external connection members being attached on the fan-out wafer of FIG. 1.

FIG. 18 is a view illustrating a capacitor being attached on the fan-out wafer of FIG. 1.

FIG. 19 is a cross-sectional view illustrating a process of cutting the fan-out wafer of FIG. 1.

FIG. 20 is a cross-sectional view illustrating a semiconductor package in accordance with example embodiments.

FIGS. 21, 22, and 23 are views illustrating a sealing member in accordance with example embodiments.

### DETAILED DESCRIPTION

Hereinafter, example embodiments will be explained in detail with reference to the accompanying drawings.

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct or indirect physical and/or electrical connection. The term “exposed” may be used to define a relationship between particular layers or surfaces, but it does not require the layer or surface to be free of other elements or layers thereon in the completed device.

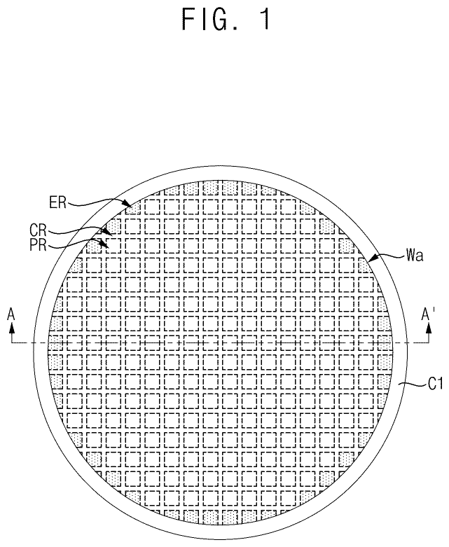

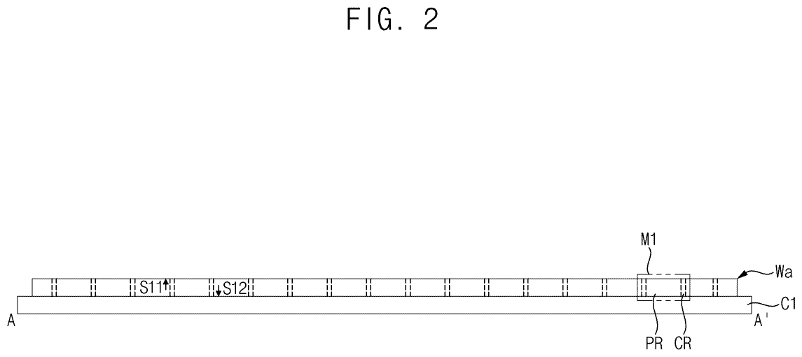

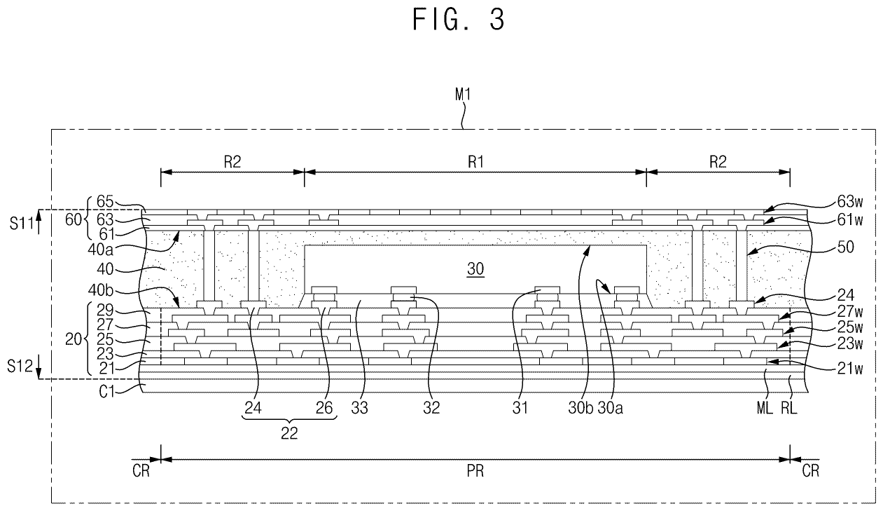

FIG. 1 is a plan view illustrating a fan-out wafer in accordance with example embodiments. FIG. 2 is a cross-sectional view taken along the line A-A′ in FIG. 1. FIG. 3 is an enlarged cross-sectional view illustrating portion ‘M1’ in FIG. 2.

Referring to FIGS. 1 to 3, a fan-out wafer Wa may be provided on a support member C1, in order to manufacture a semiconductor package. For example, the fan-out wafer may be a wafer including a plurality of semiconductor packages manufactured by a fan-out wafer level package process using a redistribution layer larger than a semiconductor chip. For example, the support member may be a glass substrate or a wafer.

Hereinafter, the fan-out wafer Wa in accordance with example embodiments will be described.

The fan-out wafer Wa may have a first surface S11 and a second surface S12 opposite to each other and may extend in a horizontal direction. For example, the fan-out wafer Wa may have a circular shape, when viewed in a plan view.

The fan-out wafer Wa may include a lower redistribution layer 20 provided on the second surface S12, a plurality of semiconductor chips 30 mounted on the lower redistribution layer 20, and a molding member 40 covering or at least partially overlapping the plurality of semiconductor chips 30 in a direction that is perpendicular to the second surface S12, and an upper redistribution layer 60 provided on the molding member 40. Additionally, the fan-out wafer may include a plurality of metal posts 50 that electrically connect the lower redistribution layer 20 and the upper redistribution layer 60, respectively.

In example embodiments, the lower redistribution layer 20 may include a plurality of lower insulation layers 21, 23, 25, 27, and 29 and a plurality of lower wirings 21w, 23w, 25w, and 27w disposed in the plurality of lower insulation layers 21, 23, 25, 27, and 29. Additionally, the lower redistribution layer 20 may include pads 22, which further include a plurality of outer pads 24 and a plurality of center pads 26 provided respectively on uppermost wirings 27w among the plurality of lower wirings 21w, 23w, 25w, and 27w.

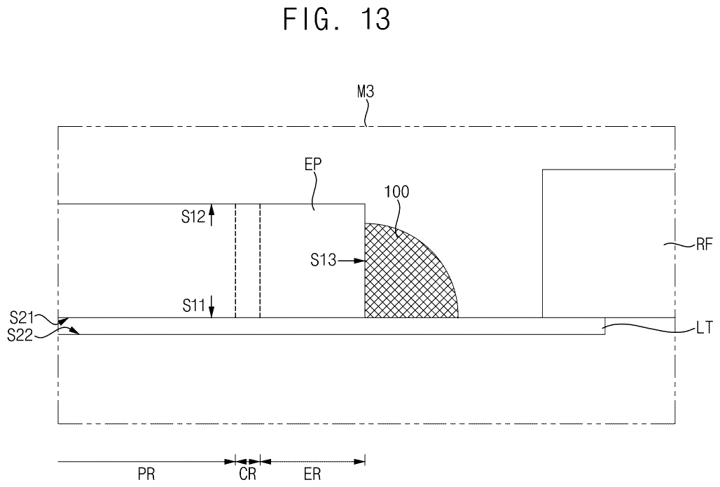

For example, the lower redistribution layers 20 may include a plurality of package regions PR in which a plurality of semiconductor packages are formed respectively and a plurality of dummy regions ER in which a plurality of dummy packages are provided respectively, which are described below in further detail with reference to FIG. 13. For example, each of the plurality of package regions PR may include a first region R1 disposed in a central region and a second region R2 surrounding at least a portion of the first region R1. Additionally, the lower redistribution layer 20 may include a cutting region CR dividing or between the plurality of package regions PR and the plurality of dummy regions ER. For example, the cutting region may be removed by a sawing process to individualize the fan-out wafer Wa into individual semiconductor packages, as described below in further detail.

In example embodiments, each of the plurality of semiconductor chips 30 may be mounted on the first region R1 of each of the plurality of package regions of the lower redistribution layer 20. For example, each of the plurality of semiconductor chips 30 may include a plurality of chip pads 31 provided on an active surface 30a thereof. Each of the plurality of semiconductor chips 30 may be mounted on the lower redistribution layer 20 via a plurality of conductive connection members 32 that are respectively provided between the plurality of chip pads 31 and the plurality of center pads 26. Additionally, an underfill member 33 may be disposed between the semiconductor chip 30 and the lower redistribution layer 20 to cover or at least partially surround the plurality of conductive connection members 32.

In example embodiments, the molding member 40 may be disposed on the lower redistribution layer 20 to cover or at least partially surround the semiconductor chip 30. For example, the molding member may be an epoxy molding compound (EMC).

In example embodiments, the plurality of metal posts 50 may be provided in the second region R2 of each of the plurality of package regions PR to be spaced apart from the semiconductor chip 30 in a horizontal direction (e.g., a direction that is parallel to the second surface S12). For example, each of the plurality of metal posts 50 may be provided on the plurality of outer pads 24, and an end portion of the metal post 50 may be exposed from or by an upper surface 40a of the molding member 40.

In example embodiments, the upper redistribution layer 60 may include a plurality of upper insulation layers 61, 63 and 65, and a plurality of upper wirings 61w and 63w disposed in the plurality of upper insulation layers 61, 63 and 65.

For example, the upper redistribution layer 60 may be provided on the upper surface 40a of the molding member 40. Lowest wirings 61w among the plurality of upper wirings 61w and 63w may be electrically connected to the end portions of the plurality of metal posts 50, respectively. For example, each of the plurality of metal posts 50 may be provided between the uppermost wiring 27w among the plurality of lower wirings 21w, 23w, 25w, and 27w and the lowermost wiring 61w among the plurality of upper wirings 61w and 63w to electrically connect the plurality of lower wirings 21w, 23w, 25w, and 27w and the plurality of upper wirings 61w and 63w.

Although the fan-out wafer Wa is illustrated in the figures, the present disclosure is not limited thereto. For example, a method of manufacturing semiconductor package in accordance with example embodiments may be applied to a wafer and a fan-in wafer including a plurality of semiconductor chips.

Hereinafter, a method of manufacturing a semiconductor package in accordance with example embodiments will be described.

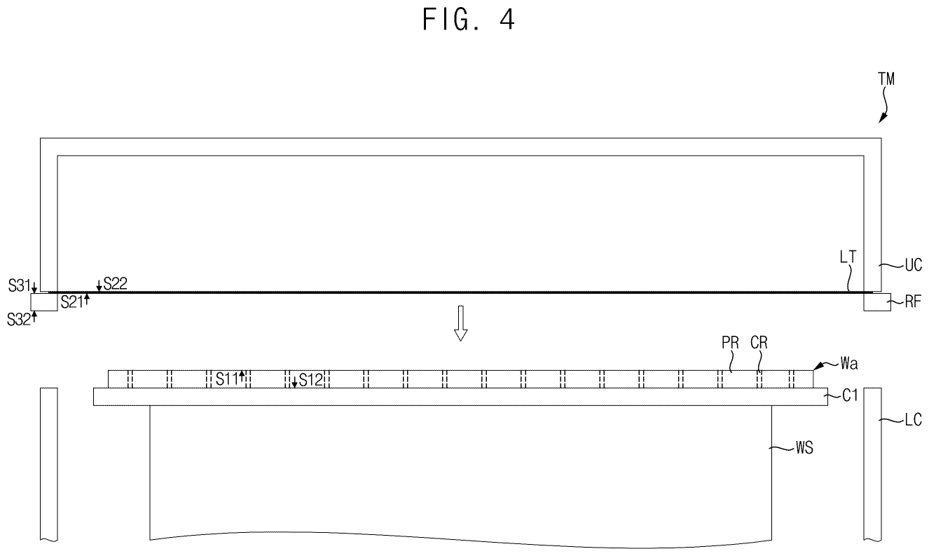

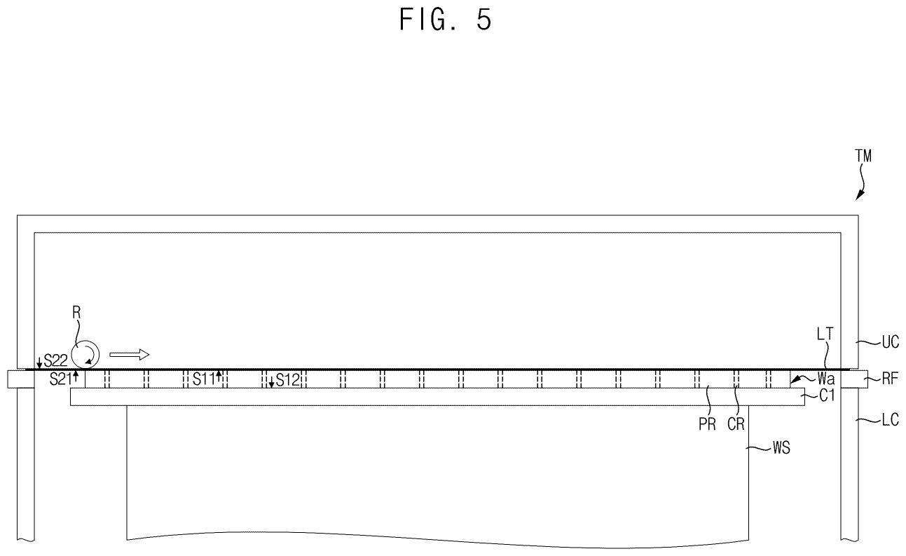

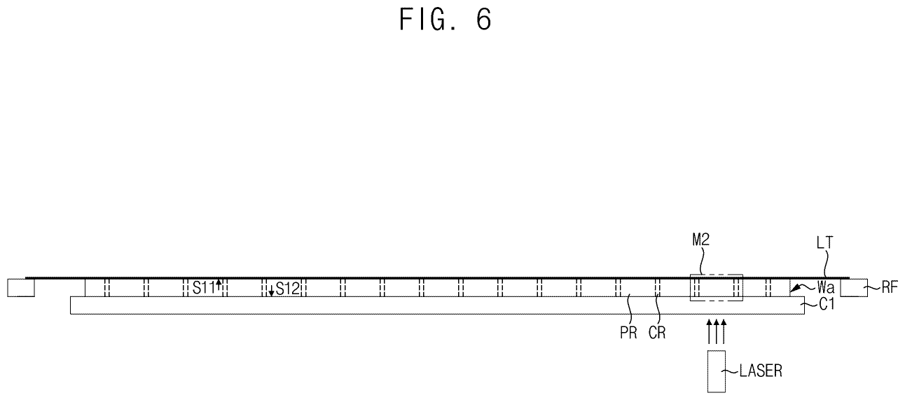

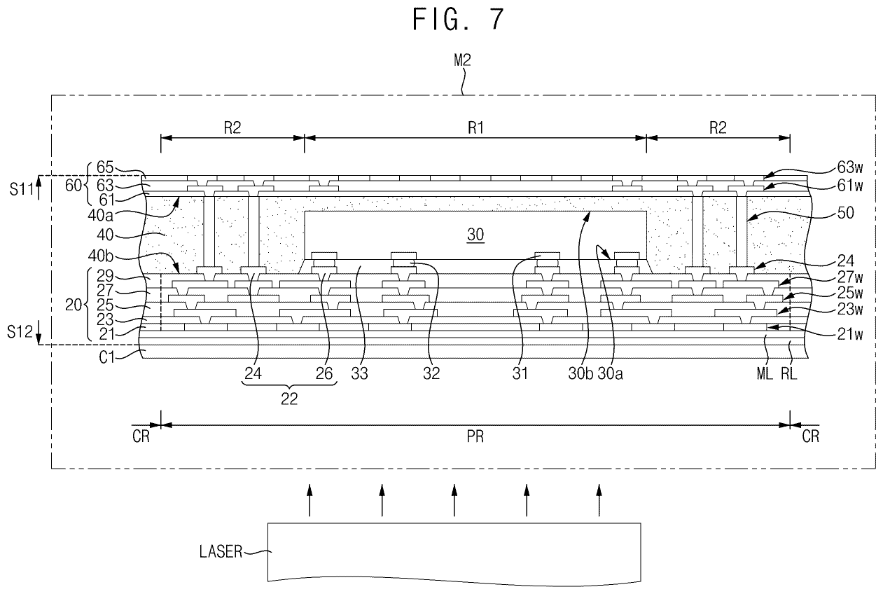

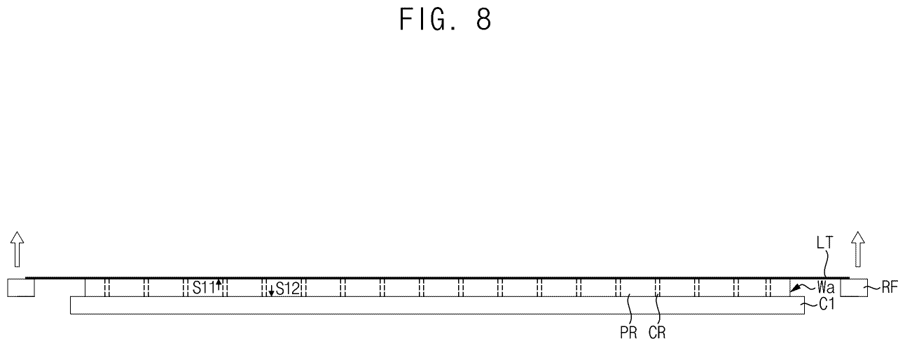

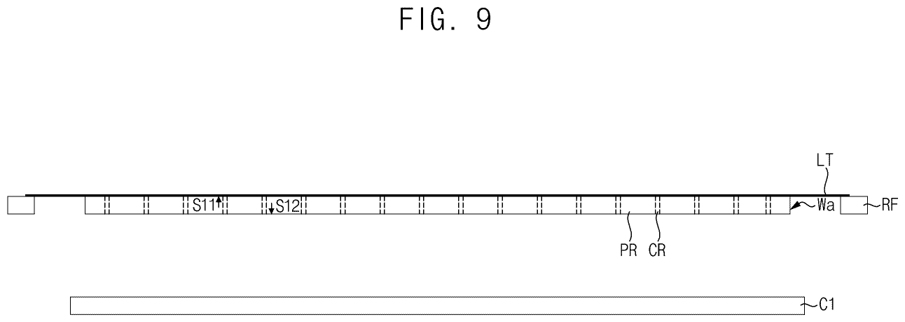

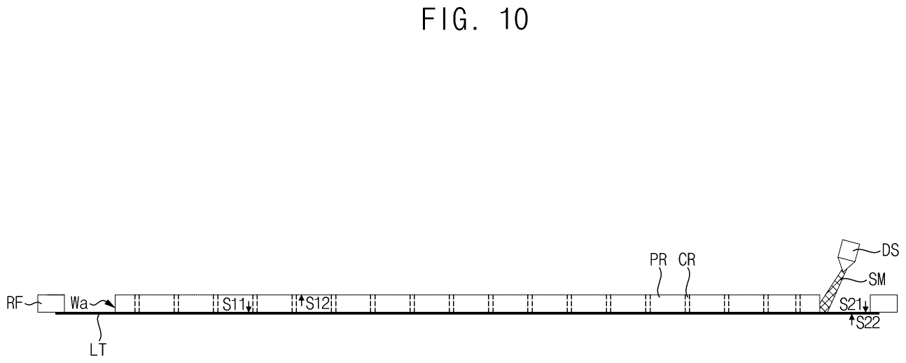

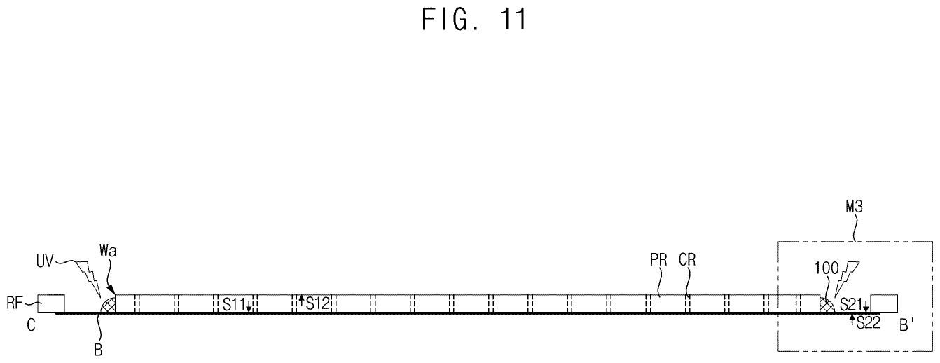

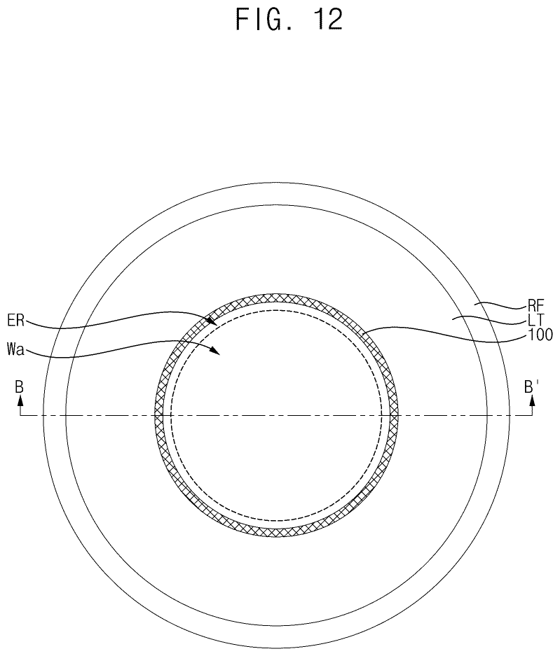

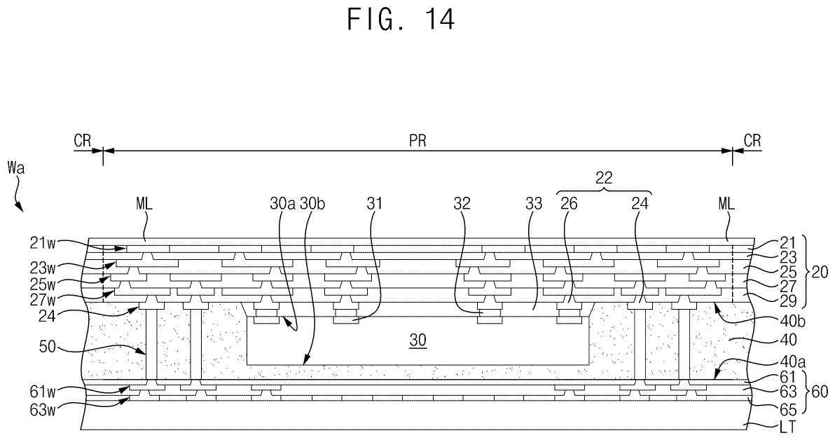

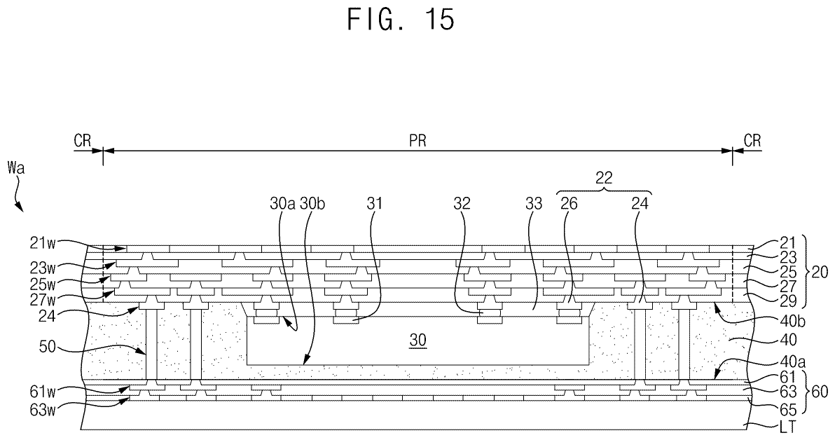

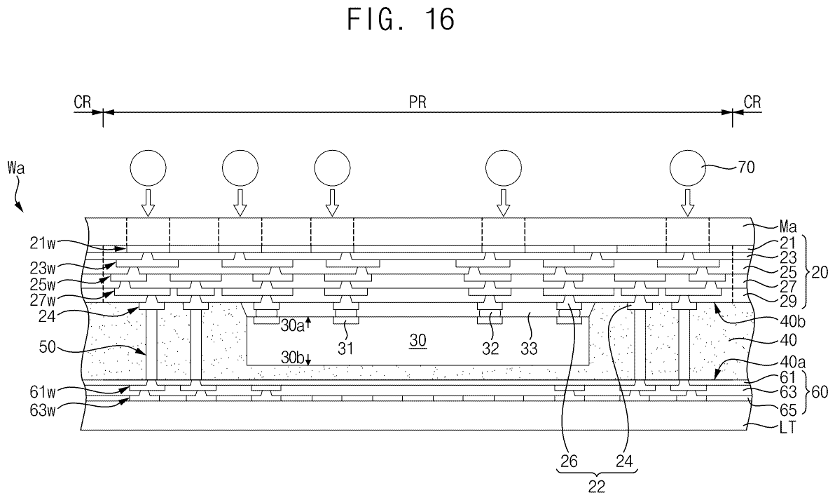

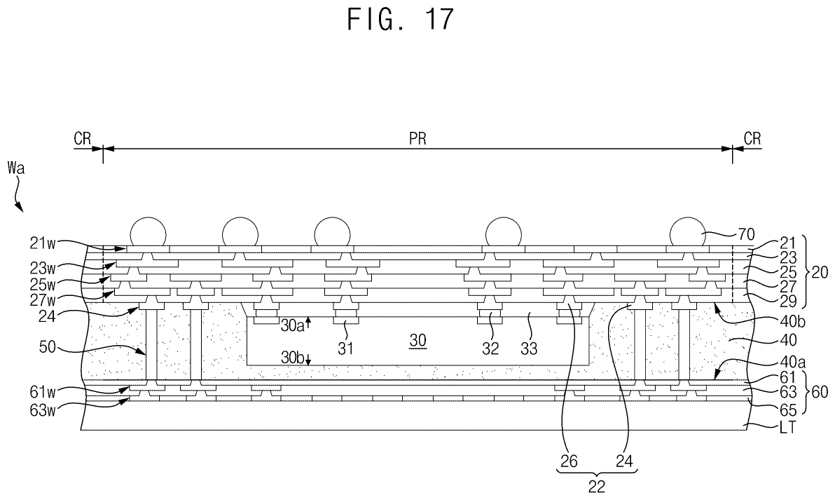

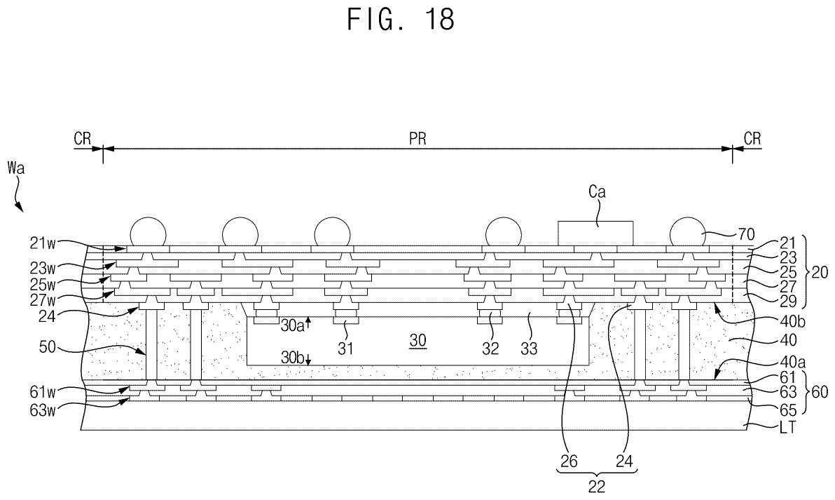

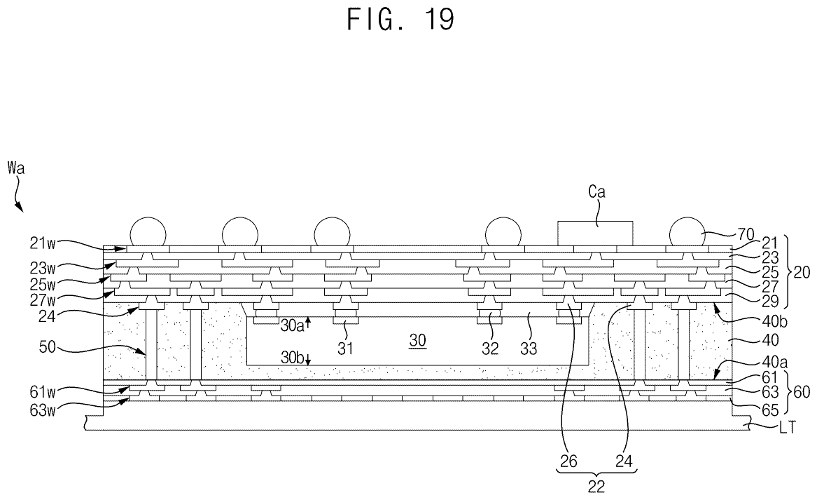

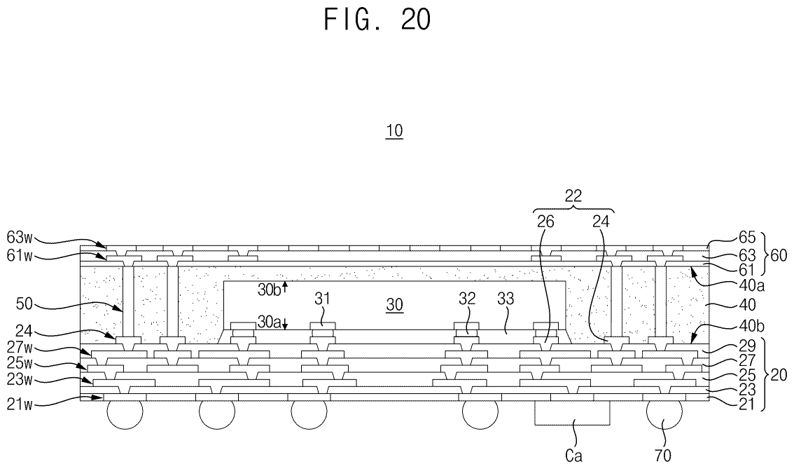

FIGS. 4 and 5 are cross-sectional views illustrating processes of attaching a ring frame on the fan-out wafer of FIG. 1 by using an adhesive member. FIG. 6 is a cross-sectional view illustrating a process of irradiating the fan-out wafer of FIG. 1 with a laser. FIG. 7 is an enlarged view illustrating portion ‘M2’ in FIG. 6. FIGS. 8 and 9 are views illustrating processes of separating the fan-out wafer of FIG. 1 from a support member. FIG. 10 is a cross-sectional view illustrating a process of forming a sealing member on the fan-out wafer. FIG. 11 is a cross-sectional view illustrating a process of irradiating the sealing member of FIG. 10, with light. FIG. 12 is a plan view illustrating the sealing member of FIG. 11. FIG. 13 is an enlarged cross-sectional view illustrating portion ‘M3’ in FIG. 11. FIGS. 14 and 15 are views illustrating a process of removing a metal layer from the fan-out wafer of FIG. 1. FIGS. 16 and 17 are views illustrating a process of attaching a plurality of external connection members on the fan-out wafer of FIG. 1. FIG. 18 is a view illustrating a process of attaching a capacitor on the fan-out wafer of FIG. 1. FIG. 19 is a cross-sectional view illustrating a process of cutting the fan-out wafer of FIG. 1. FIG. 20 is a cross-sectional view illustrating a semiconductor package in accordance with example embodiments.

Referring to FIG. 4, first, an adhesive member LT including a first surface S21 and a second surface S22 opposite to the first surface S21 may be attached to or positioned on a ring frame RF including a first surface S31 and a second surface S32 opposite to the first surface S31, and then, the fan-out wafer Wa may be loaded into a chamber of an adhesive tape attaching apparatus TM. Then, the ring frame RF with the adhesive member LT attached thereon may be transferred to a ring frame support portion in an upper chamber UC of the adhesive tape attaching apparatus TM. A support member C1 on which the fan-out wafer Wa is provided may be loaded onto a substrate support portion WS in a lower chamber LC of the adhesive tape attaching apparatus TM, and a first surface S11 of the fan-out wafer Wa may be exposed in an upwards direction (e.g., a direction that is perpendicular to the first surface S11). An adsorption plate of a ring frame transfer apparatus may adsorb the lower surface S32 of the ring frame RF and may transfer the ring frame RF to the ring frame support portion that is provided under a sidewall of the upper chamber UC. An adsorption pad formed on the ring frame support portion may adsorb and support the ring frame RF. The ring frame RF may be positioned above the fan-out wafer Wa.

Referring to FIG. 5, the upper chamber UC may be moved adjacent to the fan-out wafer Wa to be lowered, and then may be clamped with the lower chamber LC. Then, the adhesive member LT may be attached or secured to the fan-out wafer Wa by using a roller R.

For example, the ring frame may serve as a carrier frame to support the adhesive member LT and the fan-out wafer during subsequent processes of manufacturing a semiconductor package.

For example, the adhesive member LT attached to or positioned on the ring frame RF may be attached to the first surface S11 of the fan-out wafer Wa. For example, the first surface S11 of the fan-out wafer Wa and the first surface S21 of the adhesive member LT may be attached by a vacuum/roll lamination process.

Then, the adhesive member LT may be attached to or positioned on the first surface of the ring frame RF and the first surface S11 of the fan-out wafer Wa through a vacuum/roll lamination process such that the adhesive member LT connects the ring frame RF and the fan-out wafer Wa. For example, the upper chamber UC may be lowered so that the lower chamber LC and the upper chamber UC may engage with each other to form a sealed space. For example, when the adhesive member LT is clamped between the lower chamber LC and the upper chamber UC, a lower inner space may be formed in the lower chamber LC and an upper inner space may be formed in the upper chamber UC by the adhesive member LT. By generating a differential pressure between the lower inner space and the upper inner space, the adhesive member LT may be curved toward the fan-out wafer Wa to be attached on one surface S11 of the fan-out wafer Wa. During the process, the sealed space may be maintained under a low air pressure. Then, the roller R may be positioned on an upper surface of the adhesive member LT to which the ring frame RF is attached, and then may apply pressure to the upper surface of the adhesive member LT. For example, the low pressure may prevent or inhibit a void from being generated between the fan-out wafer Wa and the adhesive member LT. Then, the generated differential pressure may be released, and the fan-out wafer Wa attached to the adhesive member LT of the ring frame RF may be unloaded from the chamber of the adhesive tape attaching apparatus TM.

For example, the adhesive member may include a material that is chemically resistant and heat resistant. For example, the adhesive member may include a chemical resistant material that is resistant to chemicals used in an etching process described herein. Further, the adhesive member may include a heat-resistant material that is resistant to heat generated in a soldering process described herein. For example, a temperature of a reflow process of the soldering process may be within a range of 220° C. to 270° C.

Referring to FIGS. 6 to 9, a laser may irradiate light onto the fan-out wafer Wa to separate the fan-out wafer Wa from the support member C1. For example, the light may be irradiated on an adhesive layer RL provided on a second surface S12 of the fan-out wafer Wa. For example, the adhesive layer RL may be an adhesive member for attaching and fixing the fan-out wafer Wa to the support member C1.

For example, the fan-out wafer Wa may include a metal layer ML and the adhesive layer RL disposed sequentially on the lower redistribution layer 20. For example, the metal layer ML may be a structure for preventing or inhibiting the plurality of semiconductor chips disposed in the fan-out wafer Wa from being damaged due to the laser.

For example, the light may be irradiated onto the second surface S12 of the fan-out wafer Wa to separate the adhesive layer RL from the fan-out wafer Wa by damaging the adhesive layer RL. For example, the laser may pass through the support member C1 and the laser may reach the adhesive layer RL, thereby weakening the bond between the adhesive layer RL and the support member C1.

For example, the fan-out wafer Wa may be carried by moving the ring frame RF that holds the fan-out wafer Wa through the adhesive member LT.

Referring to FIGS. 10 to 13, a sealing material SM in a liquid state may be dispensed or provided along a circumference or edge of the fan-out wafer Wa, and then, UV light may be irradiated on the sealing material SM to cure the sealing material SM to form a sealing member 100. For example, the light may include ultraviolet light.

For example, the sealing member 100 may include a material that cures when irradiated with ultraviolet light or a thermosetting material that cures when heat is applied. Although the figures only illustrate curing the sealing member by irradiation with ultraviolet light, the present disclosure is not limited thereto. For example, the sealing member 100 may include a thermosetting material, and the sealing member 100 may be cured by applying heat.

For example, the fan-out wafer Wa may include the first surface S11 and the second surface S12 that are opposite to each other and are parallel to each other in a horizontal direction, and a third surface S13 that connects the first surface S11 and the second surface S12 and extends in a vertical direction (e.g., a direction that is perpendicular to the first surface S11). For example, the third surface S13 may be one end surface that defines the circumference or edge of the fan-out wafer Wa. For example, the fan-out wafer Wa may include a plurality of dummy packages EP in the plurality of dummy regions ER. The third surface S13 may include exposed end portions of the plurality of dummy packages EP.

For example, the adhesive member LT may have the first surface S21 in contact with the first surface S11 of the fan-out wafer Wa and the second surface S22 opposite to the first surface S21.

For example, the sealing member 100 may be formed along the circumference of the fan-out wafer Wa to connect the third surface S13 of the fan-out wafer Wa and the first surface S21 of the adhesive member LT.

Accordingly, an adhesive force between the fan-out wafer Wa and the adhesive member LT may be strengthened due to the sealing member 100. In particular, the adhesive force between the plurality of dummy packages EP provided on the plurality of dummy regions ER of the fan-out wafer Wa and the adhesive member LT may be strengthened. Thus, an interfacial delamination phenomenon, in which the fan-out wafer Wa and the adhesive member LT are separated in a subsequent process to be described later, may be prevented or inhibited.

Referring to FIGS. 14 and 15, an etching process may be performed on the second surface S12 of the fan-out wafer Wa to remove the metal layer ML that is provided on the lower redistribution layer of the fan-out wafer Wa and is configured to protect the plurality of semiconductor chips from the laser.

For example, the metal layer ML may be removed to expose the lower redistribution layer 20 of the fan-out wafer Wa. For example, the etching process may be performed to remove metallic materials, such as copper (Cu) or titanium (Ti).

Referring to FIGS. 16 to 18, a plurality of external connection members 70 and a plurality of electrical devices may be attached on each of the plurality of package regions PR of the fan-out wafer Wa.

For example, first, a flux for promoting soldering may be applied to the exposed lowermost wirings 21w of the lower redistribution layer 20 of the fan-out wafer Wa.

Then, a metal mask Ma having a plurality of openings formed therein may be provided on the lower redistribution layer 20. The plurality of openings may correspond to the exposed lowermost wirings 21w of the lower redistribution layer 20 of the fan-out wafer Wa. Then, the metal mask Ma may be aligned so that the plurality of openings correspond to the lowermost wirings 21w.

Then, the plurality of external connection members 70 may be inserted into the plurality of openings and disposed on the lowermost wirings 21w, and the plurality of external connection members 70 may be respectively attached to the lowermost wirings 21w via a reflow process. Then, de-ionized water may be used to remove residual flux.

Additionally, an electrical element Ca may be attached to portions of the lowermost wirings 21w on which the plurality of external connection members 70 are not attached. For example, the electrical element Ca may be a capacitor to improve the electrical characteristics of the semiconductor package.

Accordingly, because the interfacial delamination phenomenon that separates the fan-out wafer Wa and the adhesive member LT is prevented or inhibited, and thus the plurality of openings and the plurality of external connection members 70 may be aligned to be in their correct positions. Thus, the process error for aligning the openings and the plurality of external connection members caused by the interfacial delamination phenomenon may be reduced.

Referring to FIGS. 19 and 20, after cutting the fan-out wafer Wa along the cutting region CR using a blade, a plurality of semiconductor packages may be completed by separating each package from the adhesive member LT using a pick-up device.

For example, portions of the lower redistribution layer 20, the molding member 40, and the upper redistribution layer 60 provided in the cutting region CR of the fan-out wafer Wa may be cut by using the blade. Additionally, a portion of the adhesive member LT provided on the cutting region CR may be removed by using the blade.

Accordingly, since the interfacial delamination phenomenon in which the fan-out wafer Wa and the adhesive member LT are separated is prevented or inhibited, it may be possible to prevent a semiconductor chip from unintentionally falling off and damaging the blade during the sawing process.

As mentioned above, in a method of manufacturing a semiconductor package, the fan-out wafer Wa may be provided. The fan-out wafer may be attached on the adhesive member LT attached on the ring frame RF. The sealing member 100 may be formed on the adhesive member LT along the circumference or edge of the fan-out wafer Wa to cover or at least partially surround the plurality of dummy packages of the fan-out wafer. Then, the fan-out wafer may be cut along the cutting region to individualize a plurality of packages on the plurality of package regions.

In order to form the sealing member, the circumferential surface (or edge) of the fan-out wafer may be connected to the surface of the adhesive member through the sealing member. Additionally, while cutting the fan-out wafer, the plurality of dummy packages on the plurality of dummy regions may remain attached to the sealing member.

Accordingly, the method of manufacturing a semiconductor package may prevent or inhibit the fan-out wafer and the adhesive member from separating from each other. Thus, an interfacial delamination phenomenon may be prevented from increasing errors of the subsequent process. Furthermore, in the sawing process, the semiconductor chips may be prevented from being separated and thereby prevent or inhibit blade damage.

Hereinafter, a method of manufacturing a semiconductor package in accordance with example embodiments will be described.

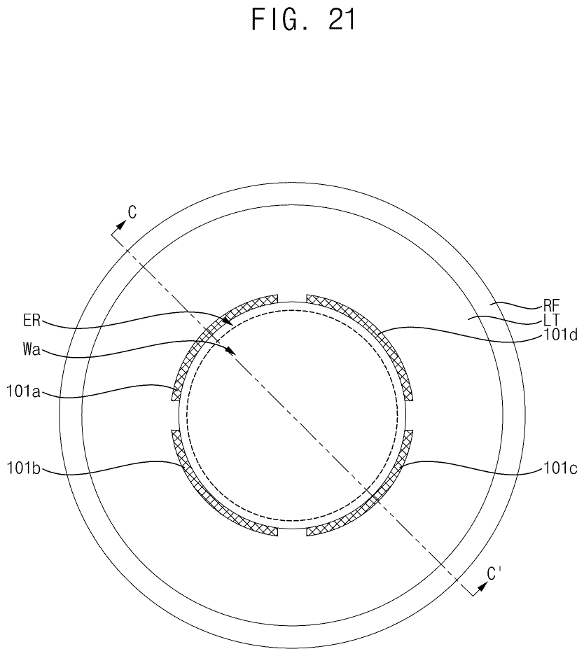

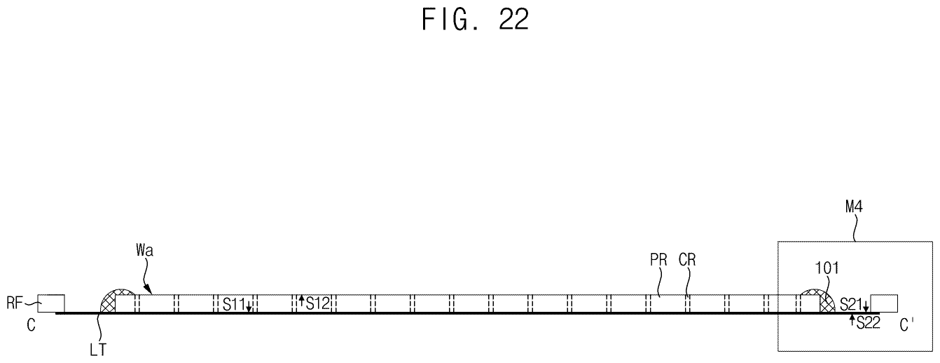

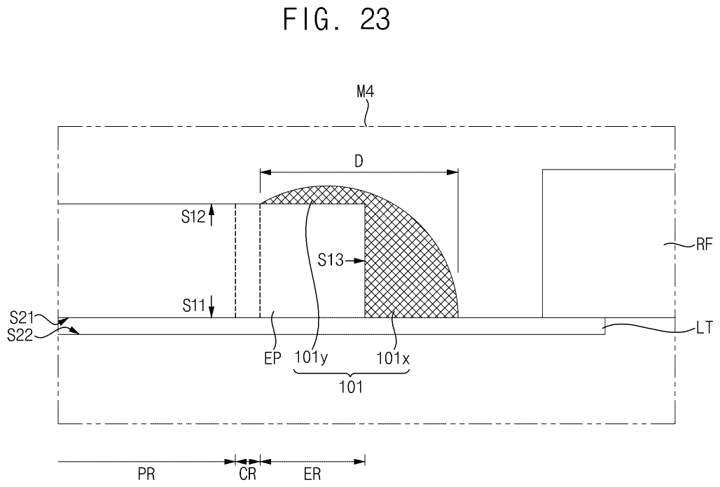

FIG. 21 is a plan view illustrating a sealing member on a fan-out wafer in accordance with example embodiments. FIG. 22 is a cross-sectional view taken along the line C-C′ in FIG. 21. FIG. 23 is an enlarged cross-sectional view illustrating portion ‘M4’ in FIG. 21.

The method of manufacturing a semiconductor package of FIGS. 21 to 23 is substantially the same as the method of manufacturing the semiconductor package described in FIGS. 1 to 20 except for a sealing member 101, so repeated descriptions of the same components will be omitted.

Referring to FIGS. 21 to 23, a sealing material may be dispensed along a circumference or edge of a fan-out wafer Wa, and then, light may be irradiated on the sealing material to cure the sealing material, to form a sealing member 101.

In example embodiments, the sealing member may be formed on portions of the circumference or edge of the fan-out wafer Wa.

For example, the sealing member 101 may include a plurality of sealing structures 101a, 101b, 101c and 101d disposed on the portions of the circumference or edge of the fan-out wafer Wa to be spaced apart from each other. For example, the fan-out wafer Wa may include first to fourth sealing structures that are disposed along the circumference or edge of the fan-out wafer Wa and spaced apart from each other along a circumferential direction.

For example, one or more of the sealing members 101a, 101b, 101c, and 101d may include a vertical structure 101x that extends in a vertical direction (e.g., a direction that is perpendicular to the first surface S11) and a horizontal structure 101y that extends in a horizontal direction (e.g., a direction that is parallel to the first surface S11) from the vertical structure 101x. For example, each of the first to fourth sealing structures 101a, 101b, 101c, and 101d may include the vertical structure 101x and the horizontal structure 101y.

The sealing member 101 may cover or at least partially surround the plurality of dummy packages of the fan-out wafer Wa. For example, the vertical structure 101x may be provided between a third surface S13 of the fan-out wafer Wa and a first surface S21 of an adhesive member LT to connect the fan-out wafer Wa and the adhesive member LT. In addition, the horizontal structure 101y may extend from the vertical structure 101x onto a plurality of dummy regions ER on a second surface S12 of the fan-out wafer Wa to connect the fan-out wafer Wa and the adhesive member LT. For example, a horizontal width of the sealing member 101 may have a first width D in a horizontal direction (e.g., a direction that is parallel to the first surface S11). For example, the first width may be about 3 mm.

Although only a few of the plurality of sealing structures are shown in the figures, the present disclosure is not limited thereto. The number, size, and arrangement of the plurality of sealing structures may vary in consideration of process costs, etc., when interfacial delamination between the fan-out wafer Wa and the adhesive member LT can be prevented.

The semiconductor package may include semiconductor devices such as logic devices or memory devices. The semiconductor package may include logic devices such as central processing units (CPUs), main processing units (MPUs), or application processors (Aps), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present disclosure. Accordingly, all such modifications are intended to be included within the scope of example embodiments as defined in the claims.

What is claimed is:

1. A method of manufacturing a semiconductor package, the method comprising:
providing a fan-out wafer on a support member, wherein the fan-out wafer comprises a plurality of package regions and a plurality of dummy regions along an edge of the fan-out wafer, and wherein the plurality of package regions are divided by a cutting region;
attaching the fan-out wafer to an adhesive member that is on a ring frame;
forming a sealing member along the edge of the fan-out wafer and on the adhesive member to at least partially surround a plurality of dummy packages on the plurality of dummy regions; and
cutting the fan-out wafer along the cutting region to separate the plurality of package regions.

2. The method of claim 1, wherein the plurality of dummy packages remain on the plurality of dummy regions while cutting the fan-out wafer.

3. The method of claim 1, wherein forming the sealing member further comprises:
providing a sealing material in a liquid state along the edge of the fan-out wafer; and
curing the sealing material by irradiating the sealing material with light.

4. The method of claim 1, wherein attaching the fan-out wafer on the adhesive member further comprises:
moving the ring frame toward the adhesive member such that a lower surface of the adhesive member and an upper surface of the fan-out wafer are in contact with each other; and
securing the fan-out wafer to the adhesive member by applying, using a roller, pressure on an upper surface of the adhesive member.

5. The method of claim 1, wherein forming the sealing member further comprises forming a plurality of sealing structures that are spaced apart from each other along the edge of the fan-out wafer.

6. The method of claim 1, wherein forming the sealing member further comprises connecting, by the sealing member, the edge of the fan-out wafer and a surface of the adhesive member.

7. The method of claim 1, wherein forming the sealing member further comprises:
forming a vertical structure of the sealing member that connects the edge of the fan-out wafer and a surface of the adhesive member, and
forming a horizontal structure of the sealing member that extends from the vertical structure onto the plurality of dummy regions of the fan-out wafer.

8. The method of claim 1, further comprising:
before cutting the fan-out wafer along the cutting region, aligning a plurality of openings of a metal mask with respective ones of a plurality of lower pads that are exposed by a surface of the fan-out wafer; and
attaching a plurality of external connection members to the respective ones of the plurality of lower pads by providing the plurality of external connection members in the plurality of openings.

9. The method of claim 8, further comprising:
before cutting the fan-out wafer along the cutting region, attaching a capacitor on a first lower pad of the plurality of lower pads.

10. The method of claim 1, wherein the fan-out wafer comprises:
a lower redistribution layer comprising the plurality of package regions and the cutting region;
at least one semiconductor chip on each of the plurality of package regions;
a molding member on the lower redistribution layer and at least partially surrounding the at least one semiconductor chip;
a plurality of metal posts that are respectively on the plurality of package regions and spaced apart from the at least one semiconductor chip in a direction that is parallel to a surface of the fan-out wafer, wherein end portions of each of the plurality of metal posts are exposed by the molding member; and
an upper redistribution layer that is on the molding member and electrically connected to the lower redistribution layer through the plurality of metal posts.

11. A method of manufacturing a semiconductor package, the method comprising:
providing a fan-out wafer on a support member, wherein the fan-out wafer comprises a plurality of dummy regions along an edge of the fan-out wafer, a plurality of package regions comprising a plurality of semiconductor chips, and a cutting region that divides the plurality of dummy regions and the plurality of package regions;
attaching the fan-out wafer to an adhesive member that is on a ring frame;
forming a sealing member on the adhesive member along the edge of the fan-out wafer to at least partially surround a plurality of dummy packages of the fan-out wafer on the plurality of dummy regions; and
attaching the adhesive member to the fan-out wafer by irradiating the sealing member with light to cure the sealing member.

12. The method of claim 11, further comprising:
cutting the fan-out wafer along the cutting region to separate the plurality of package regions.

13. The method of claim 12, wherein the plurality of dummy packages remain attached to the sealing member while cutting the fan-out wafer.

14. The method of claim 11, wherein attaching the fan-out wafer on the adhesive member further comprises:
moving the ring frame toward the adhesive member such that a lower surface of the adhesive member and an upper surface of the fan-out wafer are in contact with each other; and
securing the fan-out wafer to the adhesive member by applying, using a roller, pressure on an upper surface of the adhesive member.

15. The method of claim 11, wherein forming the sealing member further comprises forming a plurality of sealing structures that are spaced apart from each other along the edge of the fan-out wafer.

16. The method of claim 11, wherein forming the sealing member further comprises connecting, by the sealing member, the edge of the fan-out wafer and a surface of the adhesive member.

17. The method of claim 11, wherein forming the sealing member further comprises:
forming a vertical structure of the sealing member that connects the edge of the fan-out wafer and a surface of the adhesive member, and
forming a horizontal structure of the sealing member that extends from the vertical structure onto the plurality of dummy regions of the fan-out wafer.

18. The method of claim 11, further comprising:
aligning a plurality of openings of a metal mask with respective ones of a plurality of lower pads that are exposed by a surface of the fan-out wafer; and
attaching a plurality of external connection members to the respective ones of the plurality of lower pads by providing the plurality of external connection members in the plurality of openings.

19. The method of claim 18, further comprising:
attaching a capacitor on a first lower pad of the plurality of lower pads.

20. A method of manufacturing a semiconductor package, comprising:
providing a fan-out wafer on a support member, wherein the fan-out wafer comprises a first surface and a second surface that are opposite to each other and a circumferential surface extending in a first direction that is perpendicular to the first surface, wherein the fan-out wafer comprises a plurality of package regions that are on a central portion of the fan-out wafer and divided by a cutting region, and wherein the fan-out wafer comprises a plurality of dummy regions along the circumferential surface of the fan-out wafer;
attaching the fan-out wafer to an adhesive member that is on a ring frame;
forming a sealing member along the circumferential surface of the fan-out wafer and on the adhesive member to surround at least portions of the fan-out wafer on the plurality of dummy regions, wherein the sealing member connects the circumferential surface of the fan-out wafer and a surface of the adhesive member;
attaching the adhesive member to the fan-out wafer by irradiating the sealing member with light to cure the sealing member; and
cutting the fan-out wafer along the cutting regions to separate a plurality of packages on the plurality of package regions,
wherein the fan-out wafer, the adhesive member, and the sealing member are attached to each other while cutting the fan-out wafer.
